(19) United States
(12) Patent Application Publication
(10) Pub. No.: US 2013/0300452 A1
(43) Pub. Date: Nov. 14, 2013

(54) INSTRUMENT FOR MEASURING LED LIGHT SOURCE

(71) Applicant: FOXCONN TECHNOLOGY CO., LTD., New Taipei (TW)

(72) Inventor: TAY-JIAN LIU, New Taipei (TW)

(73) Assignee: FOXCONN TECHNOLOGY CO., LTD., New Taipei (TW)

(21) Appl. No.: 13/861,396

(22) Filed: Apr. 12, 2013

(30) Foreign Application Priority Data
May 8, 2012 (CN) 201210141048.5

(51) Int. Cl. G01R 31/26

(52) U.S. Cl. CPC G01R 31/2635
USPC 324/762.07

(57) ABSTRACT

A LED light source measuring instrument includes a shell portion and a test portion. The shell portion supports the test portion. The test portion includes a carrier plate for carrying a LED light source, and provides automatic electrical connections to a bottom surface of an SMT LED light source. The test portion further includes a flexible tube and a vacuum pump, at least one air hole set in the test portion, the flexible tube connecting with the air hole and the vacuum pump, the vacuum provided by the vacuum pump holding the LED light source firmly to the under test zone of the carrier plate.

### BACKGROUND

1. Technical Field

In the field of testing all aspects of LEDs, the present disclosure relates to a light emitting diode (LED) light source measuring instrument.

2. Description of Related Art

An optical and electrical measuring system of LED light source is used by inserting a measuring instrument which carries a well-positioned LED light source into an integrating sphere; through connecting a peripheral spectrum analyzer, an electrical parameter measurement instrument and a LED power controller, the chromaticity coordinate, the color temperature, the color rendering index, the color tolerance adjustment, the wavelength, the color purity, the luminous flux, the voltage, the current and the power, etc., of the LED light source can be detected. The typical LED light source used for the lighting fixture is the surface mounted technology (SMT) type LED, which is suitable for mass production. But there are many differences among the SMT LED light sources regarding the sizes, shapes, structures and types.

The electrode plates of the LED light source 203 for connecting with the power source as shown in FIG. 1 include a base positive electrode plate 2032 and a base negative electrode plate 2033 connecting with a backside of the LED light source 203 which is opposite to the light emitting surface 2031 of the LED light source 203; a longitudinal positive electrode plate 2132 and a longitudinal negative electrode plate 2133 are extending toward the longitudinal direction; a lateral positive electrode plate 2232 and a lateral negative electrode plate 2233 continue extending toward the lateral direction and parallel with the base positive and negative electrode plates 2032, 2033. In other prior arts they do not have the structure with the lateral positive electrode plate 2232 and the lateral negative electrode plate 2233. Due to the miniaturization trend and cost considerations, manufacturers only provide the SMT LED light source with the base positive and negative electrode plates 2032, 2033.

In prior art, the measuring instrument of LED light source can be divided into two types, a pressed-type measuring instrument 1a shown in FIG. 2, and a pushed-type measuring instrument 1b shown in FIG. 3. The pressed-type measuring instrument 1a includes a shell portion 10a made of a metal material in a hollow cylinder shape, and a testing portion 20a located at the opening end of the shell portion 10a. The size of an upper stage section 101a is matched with the entrance of the integrating sphere. The testing portion 20a is installed into the integrating sphere, then positioned by a stepped surface 103 which is located between the upper stage section 101a and a rear section 102a. The testing portion 20a is made of a non-metallic carrier plate 201a which is fixedly arranged at the opening end of the shell portion 10a; a pressed seat 301 is fixed on the carrier plate 201a, wherein the pressed seat 301 is made of metallic materials. A metal position adjustable bolt 302 is arranged on the pressed seat 301 along the radial direction. The nuts of the adjustable bolts 302 are connected with the different polarity power source, become as a positive electrode 205a and a negative electrode 210a which supply the power to the LED light source 203. A supporting seat 303 is arranged inside the shell portion 10a and supports an axial spring member 304. An inverted U-shaped top plate 305 is on the top of the axial spring member 304, and moves upward by spring expansion. The top plate 305 is limited and can only slide axially through the size matching between the cylindrical wall of the top plate 305 and the wall surface of the central through hole of the carrier plate 201a. The central region of the end surface of the top plate 305 is the electrically insulating under test zone.

When the pressed-type measuring instrument 1a is not placed with the LED light source 203, the end surface of the top plate 305 directly contact with the positive and negative electrodes 205a, 210a of the adjustable bolts 302. When operating, the LED light source 203 is placed on the pressed-type measuring instrument 1a, first; then the top plate 305 is pressed to adjust the position of the positive and negative electrodes 205a, 210a according to the size of the lateral positive and negative electrode plates 2232, 2233 of the LED light source 203, according to FIG. 1. The LED light source 203 is thus placed in the under test zone of the top plate 305, and makes the positive and negative electrodes 205a, 210a of the measuring instrument 1a compressing the corresponding lateral positive and negative electrode plates 2232, 2233 of the LED light source 203, respectively. To achieve the under test state, the LED light source 203 is sandwiched between the top plate 305 and the pair of electrodes 205a, 210a of the adjustable bolt 302.

Since the pressed seat 301, the adjustable bolts 302 and the pair of electrodes 205a, 210a of the pressed-type measuring instrument 1a are necessarily arranged above the light emitting surface 2031 of the LED light source 203, serious light blocking will further underestimate the measured luminous flux value, and the application of the pressed-type measuring instrument 1a is limited only in a few of the lateral positive and negative electrode plates 2232,2233 of the LED light source 203. Using this measuring instrument 1a to measure different sizes and shapes of LED light source 203 has its limitation and operating inconvenient, particularly in the non-temperature controlled test environment, resulting in the lack of reproducibility of measurement data, even causing the damage of the LED light source 203. Thus, the pressed-type measuring instrument 1a has serious limitations and shortcomings in both measuring quality and application level.

FIG. 3 shows the pushed-type measuring instrument 1b. The main differences between the pressed-type and pushed-type measuring instruments 1a, 1b are that: There is a flat shallow trench 412 through a center of a carrier plate 201b; the bottom of a negative electrode assembly 402 is fixed inside the trench 412; a positive electrode assembly 401 can slide freely along the trench 412; the positive and negative electrode assemblies 401, 402 are made of electrically insulating material. Two metal thimbles 205b, 210b extend respectively from the positive and negative electrode assemblies 401, 402 toward the LED light source 203. The two metal thimbles 205b, 210b are used to electrically connect with a power source thereby making the two metal thimbles 205b, 210b form a pair of positive and negative electrodes 205b, 210b for the pushed-type measuring instrument 1b.

The movement of the positive electrode assembly 401 is along a long trench 409 which opens through the carrier plate 201b to communicate with the trench 412. A spring member 404 is arranged inside a shell portion 10b by a screw passing through the long trench 409 to connect with the positive electrode assembly 401 so that the positive electrode assembly 401 is fixed to a slider 405. The slider 405 is in the middle of the spring member 404. One side of the slider 405 along the radial direction has a guide rod 406, the end of the guide rod 406 is extending to but no over the outer wall surface of an upper stage section 101b. The other side of the slider 405 along the radial direction locates a fixing screw 407 which extends through the upper stage section 101b, and allows a spring 408 extend into a corresponding blind hole of the slider 405. The blind hole, the guide rod 406 and the fixing screw 407 are coaxially aligned. When operating the pushed-type measuring instrument 1b, gently push a certain distance of the guide rod 406 to enable the slider 405 sliding along the trench 412, making the positive electrode assembly 401 moving the same distance away from the fixed negative electrode assembly 402 to place the LED light source 203 properly between the electrode assemblies 401, 402. When the pushed force on the guide rod 406 is released, the positive electrode assembly 401 moves close to the LED light source 203 to electrically engage the longitudinal positive electrode plate 2132.

According to the size of the LED light source 203, the positive and negative electrodes 205b, 210b of the positive and negative electrodes assembly 401, 402 of the pushed-type measuring instrument 1b contact with and supply power to the longitudinal positive and negative electrode plates 2132, 2133 of the LED light source 203. However, the heights of the positive and negative electrode assemblies 401, 402 of the pushed-type measuring instrument 1b and the longitudinal positive and negative electrode plates 2132, 2133 of the LED light source 203 are fixed and may not match each other. Additionally, the amount of the displacement of the slider 405 is limited via pushing the guide rod 406, the size of the LED light source 203 is varied in the market, and the LED light source 203 may not have the longitudinal positive and negative electrode plates 2132, 2133. Therefore, using the same pushed-type measuring instrument 1b to measure different sizes and shapes of the LED light source 203 has its limitation. The pushed-type measuring instrument 1b is only suitable for the type of the LED light source 203 with the longitudinal electrode plates 2131, 2133. Particularly in the non-temperature controlled test environment where the steady-state test conditions cannot be clearly defined. Thus, the pushed-type measuring instrument 1b has its limitations and shortcomings in measuring quality and the application level.

Therefore, it is necessary to provide a LED light source measuring instrument with no light blocking, easy operation, high precision and versatility.

### BRIEF DESCRIPTION OF THE DRAWINGS

Many aspects of the present LED light source measuring instrument can be better understood with reference to the following drawings. The components in the drawings are not necessarily drawn to scale, the emphasis instead being placed upon clearly illustrating the principles of the present LED light source measuring instrument. In the drawing, all the views are schematic.

FIG. 1 is a perspective view of a typical LED light source.

FIG. 2 is a schematic cross sectional view of a prior art measuring instrument for measuring the characteristics of the LED light source of FIG. 1.

FIG. 3 is a schematic cross sectional view of another prior art measuring instrument.

FIG. 4A is a top schematic view of a LED measuring instrument of a first embodiment of the present disclosure.

FIG. 4B is a schematic cross sectional view of the LED measuring instrument of the first embodiment of the present disclosure.

FIG. 5 is an enlarged schematic diagram of a telescopic assembly of the LED measuring instrument of FIG. 4B.

FIGS. 6A to 6C are enlarged schematic diagrams of three kinds of electrodes of the LED measuring instrument of FIG. 4B.

FIG. 7A is a top schematic view of a LED measuring instrument of a second embodiment of the present disclosure.

FIG. 7B is a schematic cross sectional view of the LED measuring instrument of the second embodiment of the present disclosure.

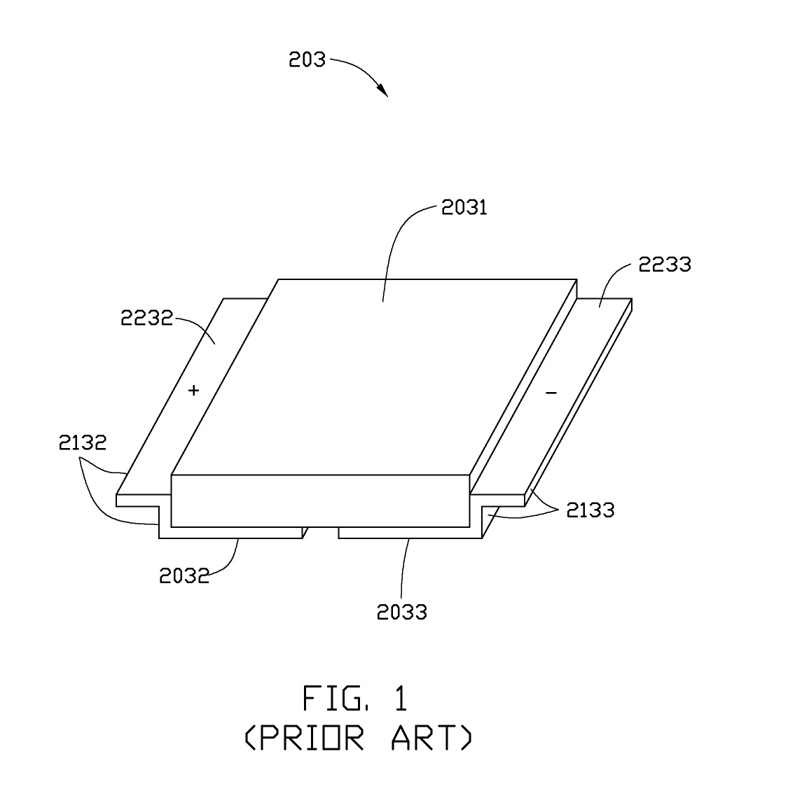

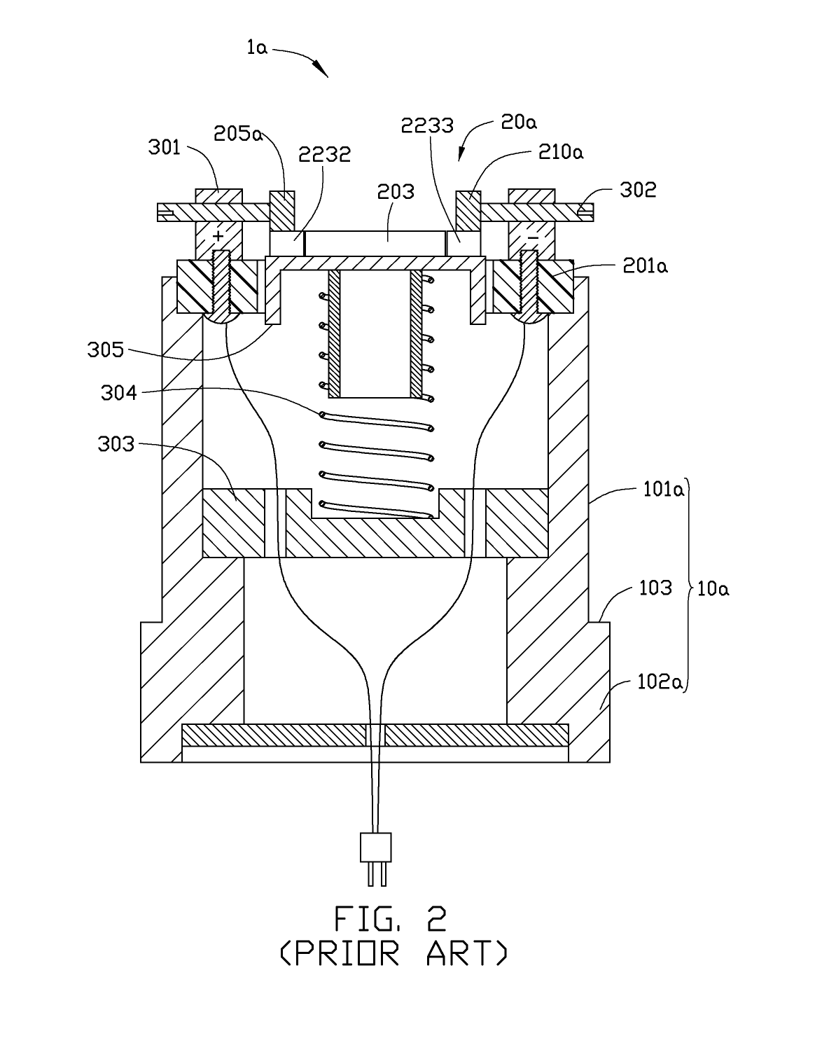

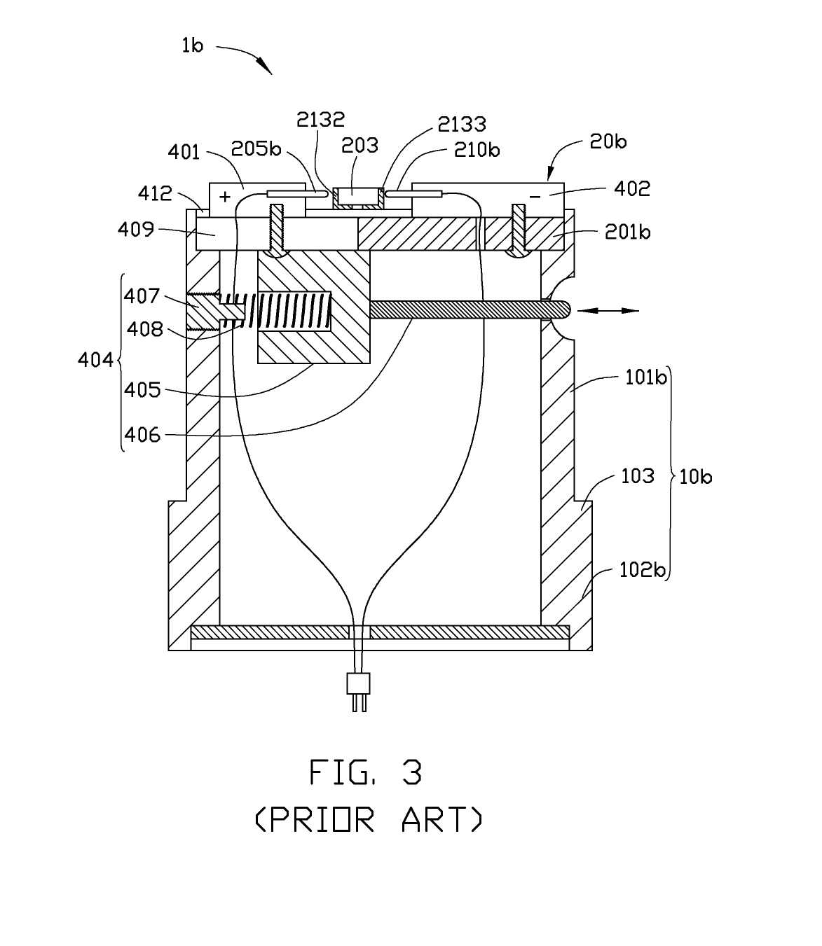

### DETAILED DESCRIPTION

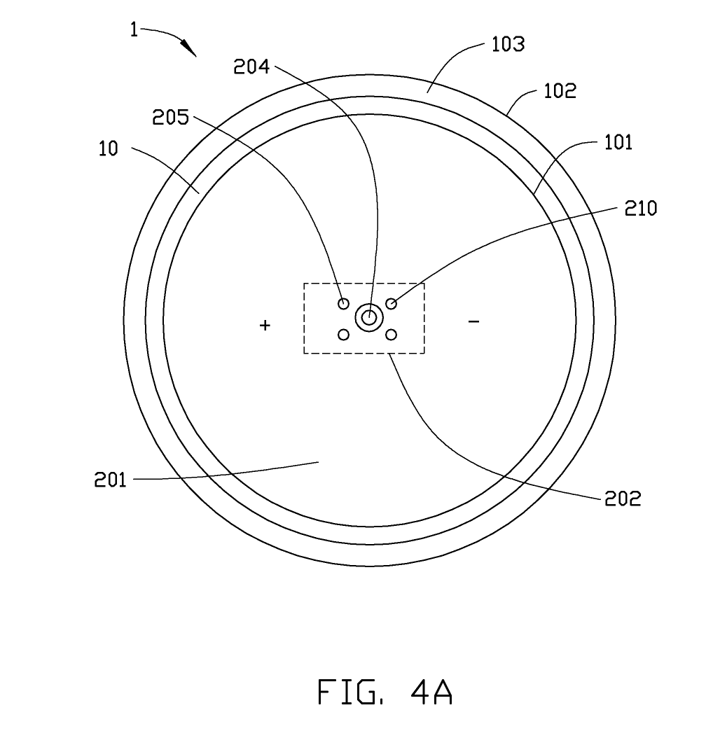

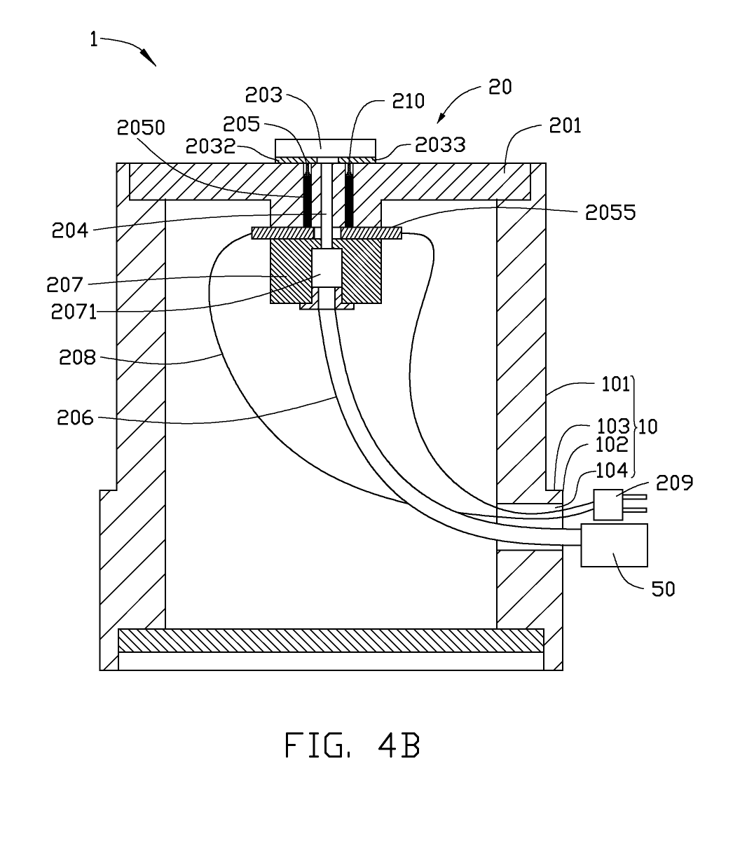

Referring to FIGS. 4 to 6, a LED measuring instrument in accordance with a first embodiment of the present disclosure is illustrated. The measuring instrument includes a shell portion 10 and a test portion 20. The shell portion 10 is a hollow cylinder and has at least one side opening for receiving the test portion 20. The outer peripheral wall surface of the cylinder axially extends from the opening into a thinner upper stage section 101, and forms a right angle stepped surface 103 between the thinner upper stage section 101 and a thicker rear section 102. The outer peripheral wall size and shape of the upper stage section 101 match the size and shape of the inner surrounding wall surface of the tubular entrance (not shown) of an integrating sphere (not shown). The stepped surface 103 abuts the tubular end of the entrance, to receive the test portion 20 inserted and positioned into the integrating sphere, so that the LED light source 203 is in under test status.

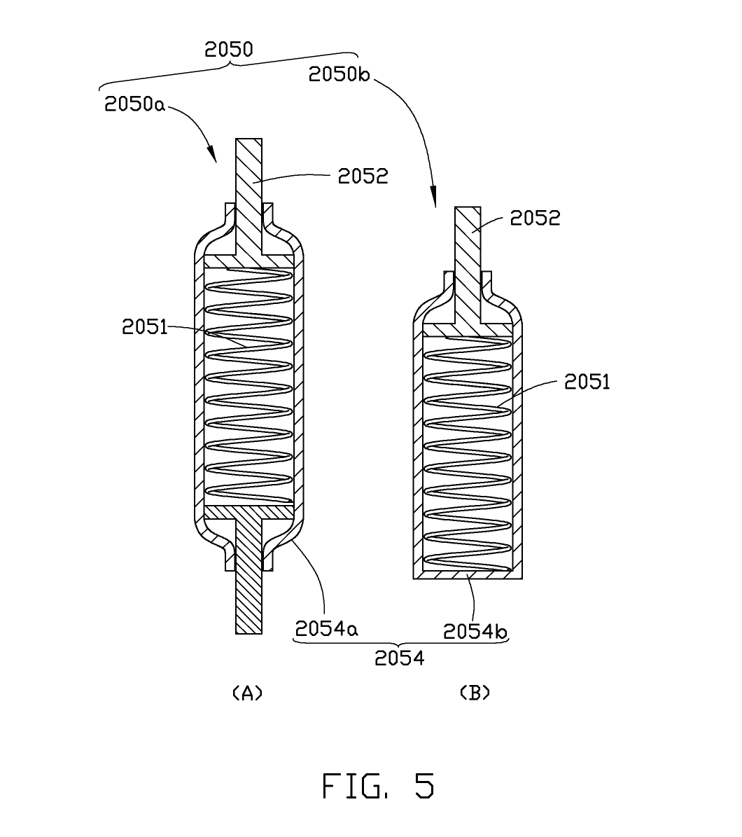

The test portion 20 includes a carrier plate 201 embedded in an opening end of the shell portion 10, and the center of the outer end surface of the carrier plate 201 is for placing the LED light source 203 in the under test zone 202, with at least one air hole 204 at the center of the under test zone 202 passing through the carrier plate 201. At the portion of the under test zone 202 which is neighboring the two diagonal sides of the air holes 204, a pair of electrodes 205, 210 is provided which is for connecting with an external control power supply (not shown) to supply driving power to the LED light source 203. Each of the electrodes 205, 210 is constituted by a metal sleeve 2054 (with an outer diameter less than 3 mm), the inside of the metal sleeve 2054 being equipped with a telescopic assembly 2050 having a metal spring 2051. One of the telescopic assemblies 2050a is composed of a sleeve 2054a with two end openings, the spring 2051 is installed inside the sleeve 2054a, and the ends of the spring 2051 are separately connected to a thimble 2052 which is axially telescopic toward the opening of the sleeve 2054a, as shown in part (A) of FIG. 5. Another telescopic assembly 2050b is composed of a sleeve 2054b with one end opening, the spring 2051 is installed inside the sleeve 2054b, and the spring 2051 is connected to a thimble 2052 which is axially telescopic toward the opening of the sleeve 2054b, as shown in part (B) of FIG. 5. Each of the electrodes 205, 210, via the corresponding sleeve 2054, perpendicularly extends and is fixed in a pore of the carrier plate 201. One end of the thimble 2052 slightly protrudes upwardly beyond the surface of the under test zone 202 when the LED light source is not placed on the under test zone 202.

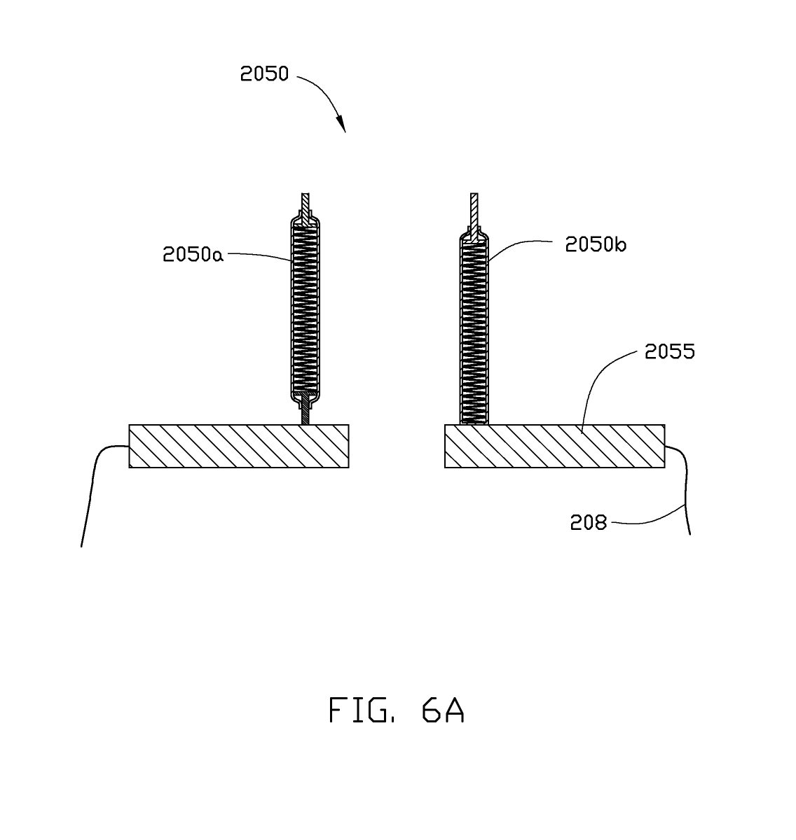

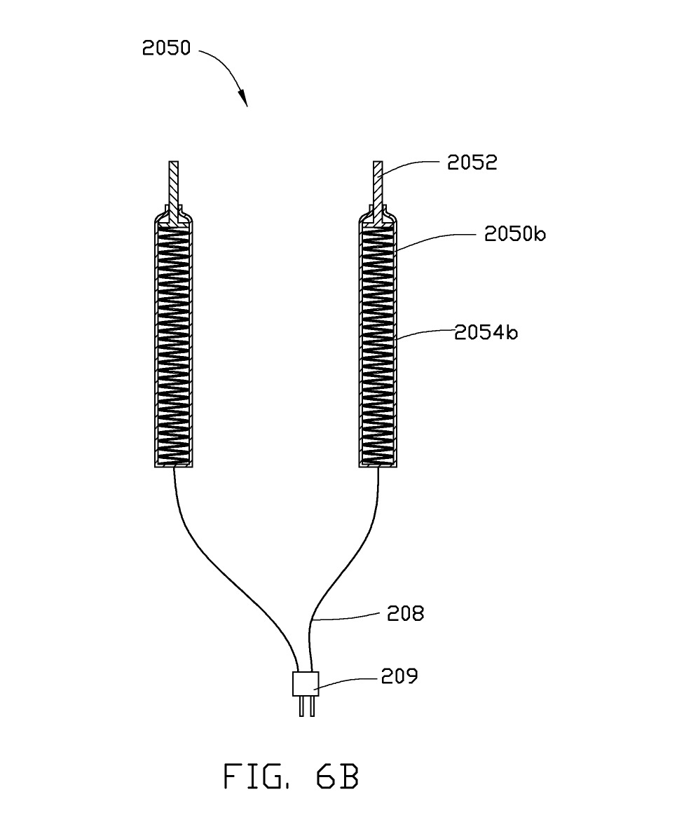

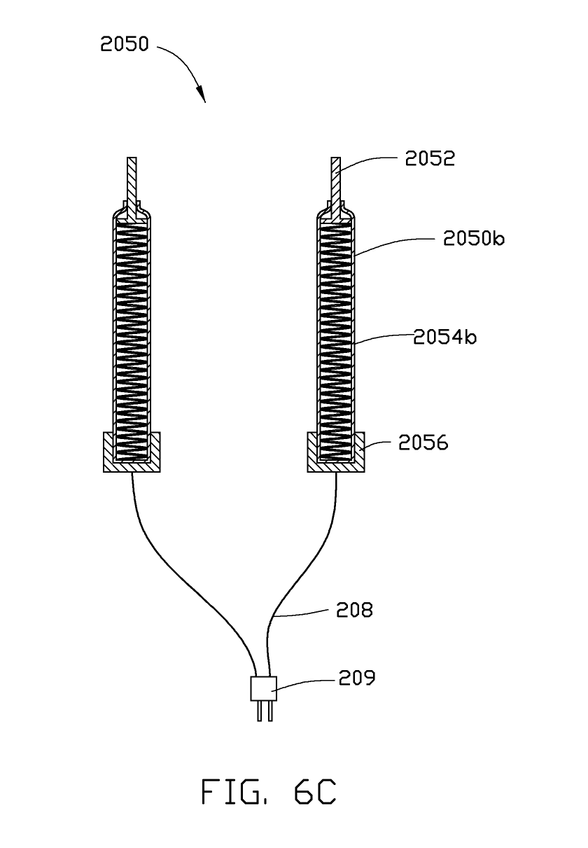

The center of the carrier plate 201 farthest from the under test zone 202 is fixedly connected to a rear seat 207 which is made of electrically insulating materials. At the center of the rear seat 207 a through hole 2071 is set which is communicated with the at least one air hole 204; furthermore, via a flexible tube 206 extending through a wall hole 104 passing through the rear section 102 of the shell portion 10, the air hole 204 is connected to the vacuum pump 50 outside the shell portion 10. The positive and negative electrodes 205, 210 are connected to the external control power supply (not shown) via two electric wires 208 using a plug 209, to supply the power to the LED light source 203. In an embodiment, as shown in FIGS. 4B and 6A, the bottom of the sleeve 2054b of a telescopic assembly 2050b is attached to or fixed on the surface of the metal plate 2055, as shown in right side of FIG. 6A. The metal plate 2055 is sandwiched between the carrier plate 201 and the rear seat 207. The two electric wires 208 are separately connected to the two metal plates 2055. The other telescopic assembly 2050a has a lower thimble 2052 which is pushed by the spring 2051 to engage with the surface of the metal plate 2055, as shown in left side of FIG. 6A. The positive and negative electrodes 205, 210 can be comprised of two telescopic assemblies 2050a, or two telescopic assemblies 2050b or one telescopic assembly 2050a and one telescopic assembly 2050b. In another embodiment, as shown in FIG. 6B, the two electric wires 208 separately connect to the bottoms of the pair of telescopic assemblies 2050b to electrically connect with the pair of sleeves 2054b and the pair of thimbles 2052. In another embodiment, as shown in FIG. 6C, the metal seats 2056 set on the tops of two branches of the electric wires 208, the metal seats 2056 being separately attached to the bottoms of the sleeves 2054b of the telescopic assemblies 2050b. The telescopic assemblies 2050b can be substituted for the telescopic assemblies 2050a.

When operating the measuring instrument 1 to measure the characteristics of the LED light source 203, first step is to turn on the vacuum pump 50, and then place the LED light source 203 on the under test zone 202, aligning the central bottom side of the LED light source 203 on the at least one air hole 204, and make the base positive and negative electrode plates 2032, 2033 abut the corresponding protruding thimbles 2052 of the pair of electrodes 205, 210 of the measuring instrument 1. The light emitting surface 2031 of the LED light source 203 is thus at the top side thereof, which is opposite to the bottom side of the base positive and negative electrode plates 2032, 2033. Through a vacuum force provided by the vacuum pump 50, the LED light source 203 is attached and positioned on the under test zone 202 via the vacuum in the air hole 204. Simultaneously, the thimbles 2052, with different polarities, separately and forcefully abut the base positive and negative electrode plates 2032, 2033 of the LED light source 203, whereby the LED light source 203 is powered to emit light. Then the measuring instrument 1 is inserted into the entrance of the integrating sphere. Adjust and stabilize the external control power supply until the operating current and voltage of the LED light source 203 meets the specification; then, turn on the power for lighting the LED light source 203 inside the integrating sphere. Confirm the temperature of the cooling surface reaches stability state by the temperature display, and startup the optical and electrical properties automatic measurement system of the LED light source 203. When measurement is completed, turn off the external control power supply to extinguish the LED light source 203, remove the measuring instrument 1 from the integrating sphere, and remove the LED light source 203, continue to place another LED light source 203 on the under test zone 202 for measurement.

Compared to the conventional LED light source measuring instruments 1a, 1b, since the present embodiment is via a vacuum pump 50 to provide a vacuum at the bottom of the LED light source 203, the present disclosure achieves the LED light source 203 not only closely attached and easily positioned on the most front surface of the measuring instrument 1, completely excluding the light blocking shortcoming of the conventional measuring instruments 1a, 1b; the measurement instrument 1 of the present disclosure also has a more simplified structure than conventional measuring instruments 1a, 1b. In the present disclosure, power can be supplied to any SMT type LED light source with base positive and negative electrode plates 2032, 2033; the present disclosure can be used to measure different sizes, shapes, structures and types of LED light sources without any restriction, and ensure the excellent measurement quality and extremely versatile of this LED light source measuring instrument 1.

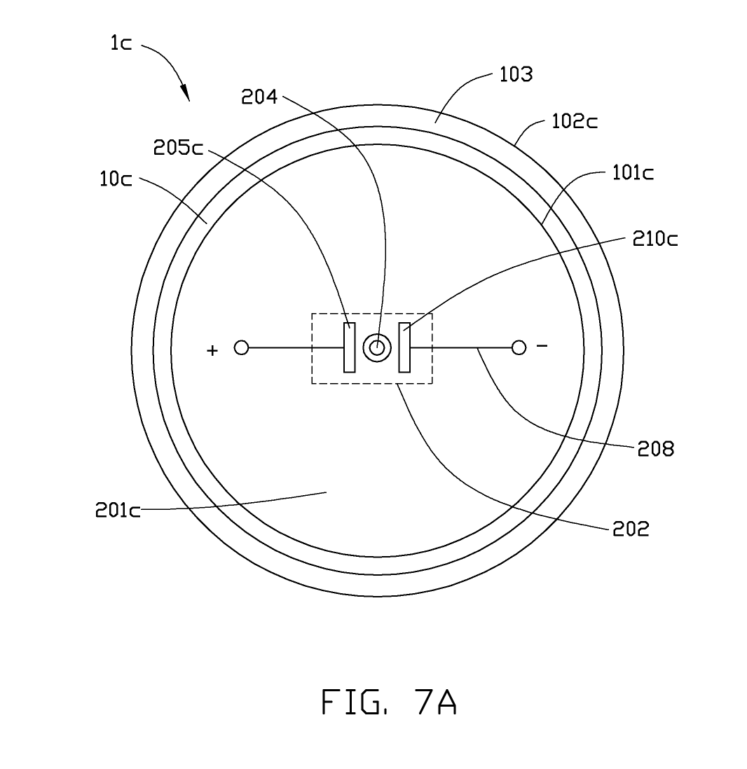

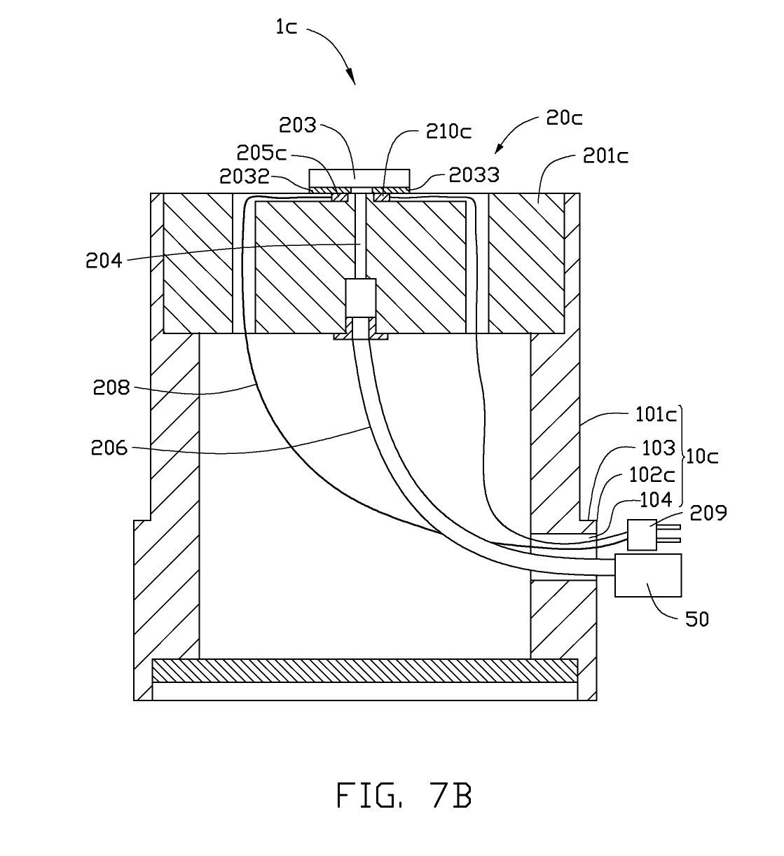

FIGS. 7A and 7B are a top and a cross sectional schematic view of a LED measuring instrument of a second embodiment of the present disclosure. The main difference between the present embodiment and the foregoing embodiment is that: To simplify the pair of electrodes 205, 210 by laying two sheet metal strips slightly protruding out of the surface of a carrier plate 201c, to form a pair of electrodes 205c, 210c which electrically insulate from the carrier plate 201c. A thicker carrier plate 201c replaces the carrier plate 201 and the rear seat 207 of the first embodiment. Obviously, the measuring instrument 1c, in addition to achieving the same benefits as the foregoing embodiment, and its advantages beyond the conventional technology, further has a streamlined structure, simplifying the process and reducing the cost.

In the above embodiments the technical features and the achieved effects of the present disclosure are clearly described, which include:

A LED light source measuring instrument is provided, which has a high ability to measure the optical and the electrical properties; a vacuum is used to easily attach and position the SMT type LED on the under test zone; and the LED is powered by connecting between the base positive and negative electrode plates of the LED and the positive and negative electrodes of the measuring instrument. The LED light source is maintained at the most front surface of the measuring instrument, to overcome the light blocking shortcoming of the conventional measuring instrument, and to achieve high precision optical and electrical performance of the measuring instrument.

The present disclosure provides an optical and electrical performance measuring instrument which can be applied to any size or type of SMT type LED, supply power to any SMT type LED light source with base positive and negative electrode plates, whether with the longitudinal or lateral positive and negative electrode plates; thus all the diversified SMT type LEDs measurement can be achieved by one LED measuring instrument of the present disclosure.

The present disclosure provides an SMT type LED measuring instrument with a simple structure, easy operation, without the positioning fixture with complex structure of the conventional measuring instrument. Thus the present disclosure can simplify the operation for the installment and removal of the LED light source, achieve lowering the cost and simplify the process of the measuring instrument, and ensure the measurement quality and the long term reliability.

Although the present disclosure has been specifically described on the basis of this exemplary embodiment, the disclosure is not to be construed as being limited thereto. Various changes or modifications may be made to the embodiment without departing from the scope and spirit of the disclosure.

What is claimed is:

1. A LED (light emitting diode) light source measuring instrument for measuring characteristics of a LED light source, comprising:
a shell portion and a test portion, the shell portion supporting the test portion, the test portion comprising a carrier plate for carrying the LED light source, a bottom surface of the LED light source with electrode plates being attached and positioned on a test zone of the carrier plate, a light emitting surface of the LED light source being away from the carrier plate, the test portion further comprising:
a flexible tube;
a vacuum pump; and
at least one air hole set in the test portion;
wherein the flexible tube being in communication with the at least one air hole and the vacuum pump, the vacuum pump applying a vacuum on the test portion to secure the LED light source to the test zone.

2. The LED light source measuring instrument as claimed in claim 1, wherein the test portion comprises a pair of electrodes, the pair of electrodes comprises a positive electrode and a negative electrode, each electrode passing through and positioned in the carrier plate and electrically connecting with a corresponding electrode plate of the LED light source.

3. The LED light source measuring instrument as claimed in claim 2, wherein each of the electrodes comprises a telescopic assembly and at least one thimble, the telescopic assembly comprises a metal sleeve and a spring being equipped inside the metal sleeve, the spring is connected to the at least one thimble which is axially telescopic toward an opening of the metal sleeve and in electrical connection with the corresponding electrode plate of the LED light source.

4. The LED light source measuring instrument as claimed in claim 3, wherein two metal plates are positioned under the carrier plate, the sleeves of the pair of electrodes are respectively electrically connected to the metal plates.

5. The LED light source measuring instrument as claimed in claim 3, wherein bottoms of the pair of electrodes are separately electrically connected with an external control power supply using conductive wires directly connecting with the bottoms of the pair of electrodes, whereby power from the external control power supply is supplied to the LED light source.

6. The LED light source measuring instrument as claimed in claim 3, wherein bottoms of the pair of electrodes are separately set inside metal seats, each metal seat connecting with a conductive wire and connecting with an external control power supply via the conductive wire, whereby power is supplied to the LED light source.

7. The LED light source measuring instrument as claimed in claim 1, further comprising an electrically insulating rear seat, the rear seat set on a bottom side of the carrier plate opposite the LED light source, at the center of the rear seat a through hole being defined which connects with at least one air hole, and via the flexible tube the through hole being connected with the vacuum pump, thereby enabling the at least one air hole connecting with the vacuum pump which is located outside the shell portion.

8. The LED light source measuring instrument as claimed in claim 2, wherein the pair of electrodes each is formed as a sheet metal strip, and the sheet metal strip is electrically connecting with the corresponding electrode plate of the LED light source.

9. The LED light source measuring instrument as claimed in claim 1, wherein the shell portion is a hollow cylinder and has at least one side opening, an outer peripheral wall surface of the shell portion comprises a upper stage section and a rear section, and forms a right angle steeped surface between the upper stage section and the rear section, and a radial dimension of the upper stage section is less than a radial dimension of the rear section.

10. The LED light source measuring instrument as claimed in claim 9, wherein the rear section of the shell portion set a wall hole, the flexible tube extends through the wall hole to pass through the rear section of the shell portion to connect with the vacuum pump which is located outside the shell portion.
